(19) United States
(12) Patent Application Publication
(10) Pub. No.: US 2013/0241903 A1
(43) Pub. Date: Sep. 19, 2013

(54) OPTICAL STACK FOR CLEAR TO MIRROR INTERFEROMETRIC MODULATOR

(71) Applicant: Marc Maurice Mignard, San Jose, CA (US)

(72) Inventor: Marc Maurice Mignard, San Jose, CA (US)

(73) Assignee: QUALCOMM MEMS Technologies, Inc., San Diego, CA (US)

(21) Appl. No.: 13/589,647

(22) Filed: Aug. 20, 2012

Related U.S. Application Data
(60) Provisional application No. 61/612,163, filed on Mar. 16, 2012.

(51) Int. Cl. G02B 26/00; C23C 16/44; B05D 5/06; G09G 3/00; G06F 3/038

(52) U.S. Cl. 345/204; 359/290; 345/32; 427/58; 427/569

(57) ABSTRACT

This disclosure provides systems, methods and apparatus for electromechanical systems devices that can be switched between a transmissive state and a reflective state. In one aspect, the electromechanical systems devices can include a partially transmissive and a partially reflective layer that has a high refractive index and a low absorption coefficient. The electromechanical systems devices can be used in a variety of way including as a smart window, as an optical shutter, as a privacy screen and as a display device.

### CROSS-REFERENCE TO RELATED APPLICATIONS

This disclosure claims priority to U.S. Provisional Patent Application No. 61/612,163, filed on Mar. 16, 2012, entitled “Electro-Mechanical Systems Based Display Device Including Clear to Mirror Optical Stack,” and assigned to the assignee hereof. The disclosure of the prior application is considered part of, and is incorporated by reference in, this disclosure.

### TECHNICAL FIELD

This disclosure relates to the field of display devices and more particularly to electromechanical systems based display devices.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Devices including electromechanical systems may be used for a variety of purposes including as displays for electronic systems. Such devices may be transmissive, reflective or transflective. Implementations that enhance the transmittance and/or reflectance properties of such devices are desirable.

### SUMMARY

The systems, methods and devices of the disclosure each have several innovative aspects, no single one of which is solely responsible for the desirable attributes disclosed herein.

One innovative aspect of the subject matter described in this disclosure can be implemented in an electromechanical device comprising a substrate, an optical stack disposed over the substrate and a movable layer disposed over the optical stack. The optical stack includes an index matching layer and a first at least partially transmissive and at least partially reflective layer. The index matching layer is disposed between the substrate and the first layer. The movable layer and the optical stack define a cavity therebetween. The movable layer is configured to move through the cavity and includes a second at least partially transmissive and at least partially reflective layer, and a dielectric layer disposed on the second layer such that the second layer is between the cavity and the dielectric layer. The index of refraction of the first and the second layer can be greater than approximately 3.0.

In various implementations of the electromechanical device the first and the second layer can have an extinction coefficient characteristic less than approximately 0.1. In various implementations, the index matching layer can include aluminum oxide (Al2O3) and/or the first layer can include gallium phosphide (GaP) and/or the second layer can include gallium phosphide (GaP). In various implementations, the index matching layer can be configured to match the refractive index of the first layer with the refractive index of the substrate. In various implementations, the movable layer is movable between a first position when the cavity is collapsed to a second position when the cavity is not collapsed, the first position being closer to the optical stack than the second position. In various implementations, the device can be configured to reflect light incident on the substrate when the movable layer is in the first position. In various implementations, the device can be transmissive of light incident on the substrate when the movable layer is in the second position. In various implementations, the device can be configured to move the movable layer to the first and the second position by the application of electrostatic forces, mechanical forces or using vacuum. In various implementations the cavity can be an interferometric cavity. In various implementations, the thickness of the first and second layer can be between approximately 20 nanometers and approximately 40 nanometers. In various implementations, the index matching layer can have a thickness between approximately 60 nanometers and approximately 90 nanometers. In various implementations, the dielectric layer can have a thickness between approximately 60 nanometers and approximately 100 nanometers. In various implementations, the cavity can include an insulating layer between the movable layer and the fixed optical stack. In various implementations, the first and/or the second layer can be resistive. In various implementations the resistivity of the first and/or the second layer can be about 100 ohm-meter.

Another innovative aspect of the subject matter described in this disclosure can be implemented in an electromechanical device comprising a substrate, an optical stack disposed over the substrate and a movable layer disposed over the optical stack. The optical stack includes a means for refractive index matching and a first means for partially transmitting and partially reflecting light, wherein the refractive index matching means is disposed between the substrate and the first partially transmitting and partially reflecting means. The movable layer and the optical stack include a means for producing optical resonance therebetween, the movable layer is configured to move through the optical resonance producing means using a means for actuating the movable layer. The movable layer includes a second means for partially transmitting and partially reflecting light, and a dielectric layer disposed on the second partially transmitting and partially reflecting means such that the second partially transmitting and partially reflecting means is between the optical resonance producing means and the dielectric layer. The index of refraction of the first and second partially transmitting and partially reflecting means is greater than approximately 3.0.

In various implementations, the refractive index matching means can include a refractive index matching layer, or the first means for partially transmitting and partially reflecting light can include a partially transmissive and a partially reflective layer, or the second means for partially transmitting and partially reflecting light can include a partially transmissive and a partially reflective layer, or the optical resonance producing means can include an optical resonant cavity. In various implementations, the actuating means can include a device configured to provide an electrostatic force or a mechanical force. In various implementations, the first and second partially transmitting and partially reflecting means can have an absorption coefficient characteristic less than approximately 0.1.

Another innovative aspect of the subject matter described in this disclosure can be implemented in a method of manufacturing an electromechanical device, the method comprises providing a substrate, providing an optical stack and providing a movable layer disposed over the optical stack. The optical stack is disposed over the substrate and includes a refractive index matching layer and a first at least partially transmissive and partially reflective, the refractive index matching layer disposed between the substrate and the first partially transmissive and partially reflective layer. The movable layer and the optical stack include a cavity therebetween. The movable layer is configured to move through the cavity, the movable layer includes a second at least partially transmissive and a partially reflective layer having a refractive index greater than approximately 3.0 and an absorption coefficient characteristic less than approximately 0.1, and a dielectric layer disposed on the conducting layer such that the second partially transmissive and partially reflective layer is between the cavity and the dielectric layer.

In various implementations, the first partially transmissive and partially reflective layer can be formed by a process including at least one of: physical vapor deposition, chemical vapor deposition, plasma-enhanced chemical vapor deposition, thermal chemical vapor deposition and spin-coating. In various implementations, the second partially transmissive and partially reflective layer can be formed by a process including at least one of: physical vapor deposition, chemical vapor deposition, plasma-enhanced chemical vapor deposition, thermal chemical vapor deposition and spin-coating. In various implementations, the method can further comprise providing a conducting frame around the movable layer, the conducting frame configured for use in actuating the movable layer.

Another innovative aspect of the subject matter described in this disclosure can be implemented in a display device comprising a substrate, an optical filter disposed over the substrate, an optical stack disposed over the optical filter and a movable layer disposed over the optical stack. The optical stack includes an index matching layer and a first at least partially transmissive and partially reflective layer, the index matching layer is disposed between the substrate and the first layer. The movable layer and the optical stack define a cavity therebetween. The movable layer is configured to move through the cavity when actuated and includes a second at least partially transmissive and partially reflective layer, the second layer having an refractive index characteristic greater than approximately 3.0 and an absorption coefficient characteristic less than approximately 0.1 and a dielectric layer disposed on the second layer such that the second layer is between the cavity and the dielectric layer. The movable layer is movable to a first position in an actuated state and to a second position in an unactuated state, the first position being closer to the optical stack than the second position. The movable layer and the optical stack are configured to be substantially transmissive when the movable layer is in the second position and substantially reflective when the movable layer is in the first position.

In various implementations, when the device is in the reflective first position, a color displayed on the display device can be substantially the same hue within a viewing angle of approximately 60 degrees with respect to a normal to a plane defined by a portion of the substrate. In various implementations, the substrate can include a black backing layer such that the display device will appear black when the movable layer is positioned in the second position. In some implementations, the optical stack can include a diffuser such that the display device will appear white when the movable layer is in the first position. In various implementations, the device can be an interferometric modulator.

Another innovative aspect of the subject matter described in this disclosure can be implemented in a display device, comprising a substrate, a means to filter light, the filtering means disposed over the substrate, an optical stack disposed over the substrate, and a movable layer disposed over the optical stack. The optical stack includes a means for refractive index matching and a first at least partially transmissive and partially reflective layer. The refractive index matching means is disposed between the substrate and the first at least partially transmissive and partially reflective layer. The movable layer and the optical stack include a cavity therebetween. The movable layer is configured to move through the cavity when actuated and includes a second at least partially transmissive and partially reflective layer having a refractive index characteristic greater than approximately 3.0 and an absorption coefficient characteristic less than approximately 0.1, and a dielectric layer disposed on the second layer such that the second layer is between the cavity and the dielectric layer. The movable layer is movable to a first position in an actuated state and to a second position in an unactuated state, the first position being closer to the optical stack than the second position. The movable layer and the optical stack are configured to be transmissive when the movable layer is in the second position and reflective when the movable layer is in the first position. In various implementations, the filtering means can include an optical filter and/or the refractive index matching means can include a refractive index matching layer.

Another innovative aspect of the subject matter described in this disclosure can be implemented in a method of manufacturing an electromechanical display device, the method comprises providing a substrate, providing an optical filter disposed over the substrate, providing an optical stack disposed over the substrate and providing a movable layer disposed over the optical stack. The optical stack includes a refractive index matching layer and a first at least partially transmissive and partially reflective layer, the refractive index matching layer is disposed between the substrate and the first layer. The movable layer and the optical stack include an optical resonant cavity therebetween. The movable layer is configured to move through the cavity and includes a second at least partially transmissive and partially reflective layer having a refractive index greater than approximately 3.0 and an absorption coefficient characteristic less than approximately 0.1, and a dielectric layer disposed on the second layer such that the second layer is between the cavity and the dielectric layer.

In various implementations, the first partially transmissive and partially reflective layer can be formed by a process including at least one of: physical vapor deposition, chemical vapor deposition, plasma-enhanced chemical vapor deposition, thermal chemical vapor deposition and spin-coating. In various implementations, the second partially transmissive and partially reflective layer can be formed by a process including at least one of: physical vapor deposition, chemical vapor deposition, plasma-enhanced chemical vapor deposition, thermal chemical vapor deposition and spin-coating. In various implementations, the method further comprises providing a conducting frame around the movable layer, the conducting frame can be configured for use in actuating the movable layer.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9A-9D illustrate implementations of an electromechanical systems device, which can include an interferometric modulator, that can be switched between a transmissive state and a reflective state.

FIGS. 10A-10D illustrate implementations of a display element that include an electromechanical systems device.

FIG. 11 illustrates a simulated reflectance spectrum of an implementation of a display element similar to the display element illustrated in FIGS. 10A-10D.

FIGS. 12A and 12B illustrate simulated chromaticity diagram of an implementation of a display device including a plurality of display elements similar to the display element illustrated in FIGS. 10A-10D.

FIGS. 13A and 13B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

As discussed below, in certain implementations, an electromechanical systems device includes a fixed layer disposed on a substrate, and a movable layer disposed over the fixed layer. The device can be configured such that the device is transmissive allowing visible light incident on the substrate to propagate through the device when the movable layer is positioned at a location (a first position) a certain distance away from the fixed layer. The device can be further configured such that the device reflects visible incident light when the movable layer is positioned at a location (a second position) which is closer to the fixed layer than the first position. In some implementations, the electromechanical systems device can transmit incident light when the movable layer is placed at a location a first distance from the fixed layer (e.g., a first position). In such a “clear” state, the device can appear clear to a viewer viewing the device. In certain implementations, the electromechanical systems device can reflect almost all the incident light when the movable layer is placed at a location a second distance from fixed layer (a second position) such that the device appears highly reflective and mirror-like to a viewer viewing the electromechanical systems device through the substrate. The light transmission and light reflection capacity of the electromechanical systems device can be enhanced by including a layer of material (for example, gallium phosphide (GaP)) having a refractive index (n) greater than approximately three (3) and an absorption coefficient (k) less than about 0.1 in the device structure. In various implementations, the absorption coefficient (k) can be approximately zero (0).

In certain implementations, an electromechanical systems device that can be switched from a transmissive (or “clear”) state to a reflective (or “mirror”) state can be used in a display device to display a variety of colors. For example, the electromechanical systems device can be configured to display a black color in the transmissive state by providing a black backing on a side of the electromechanical systems device opposite the substrate away from a side of the device exposed for viewing. As another example, the electromechanical systems device can be configured to display a white color in the reflective state by providing a diffuser. As yet another example, the electromechanical systems device can be configured to display a color (for example, red, green, blue, yellow, etc.) in the reflective state by providing an optical color filter.

Particular implementations of the subject matter described in this disclosure can be implemented to realize one or more of the following potential advantages. Electromechanical systems devices that are capable of switching from a transmissive (clear) state to a reflective (mirror) state can be included in window panes to control the amount of light entering a room. Such devices can also be used in privacy screens, as a camera shutter or in any other application where it is desirable to control the amount of light transmitted or reflected. In display devices, such electromechanical systems devices can be used to switch from displaying black color to displaying white color so as to provide grey scale control. Such electromechanical systems devices can also be configured to display a bright white. In some implementations, a display device including the electromechanical systems devices described herein can be approximately 30% brighter than other available display devices. In various implementations, the view angle dependence of the color displayed by display devices that include such electromechanical systems devices may be reduced to provide display devices that are viewable over a wide angular range. The materials for the various layers of the electromechanical systems devices and their thickness can be selected to achieve a reflectance spectrum that is flat for wavelengths in the visible spectral region. This can enable the display devices that include such electromechanical systems devices to have reduced or almost no color shift when viewed over a wide angular width.

An example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

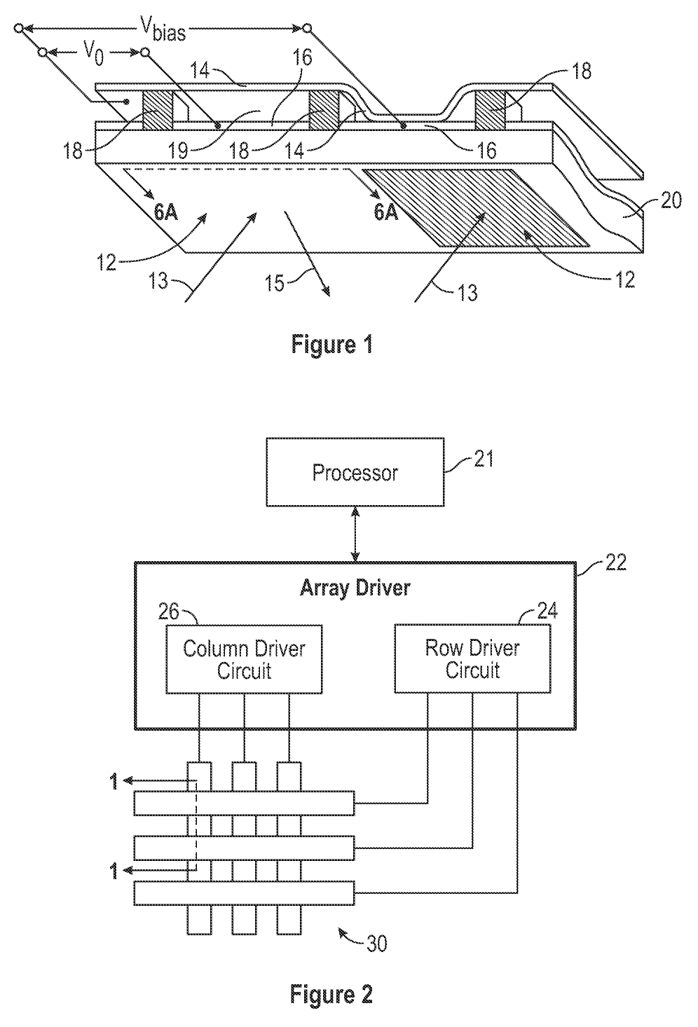

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when actuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows indicating light 13 incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

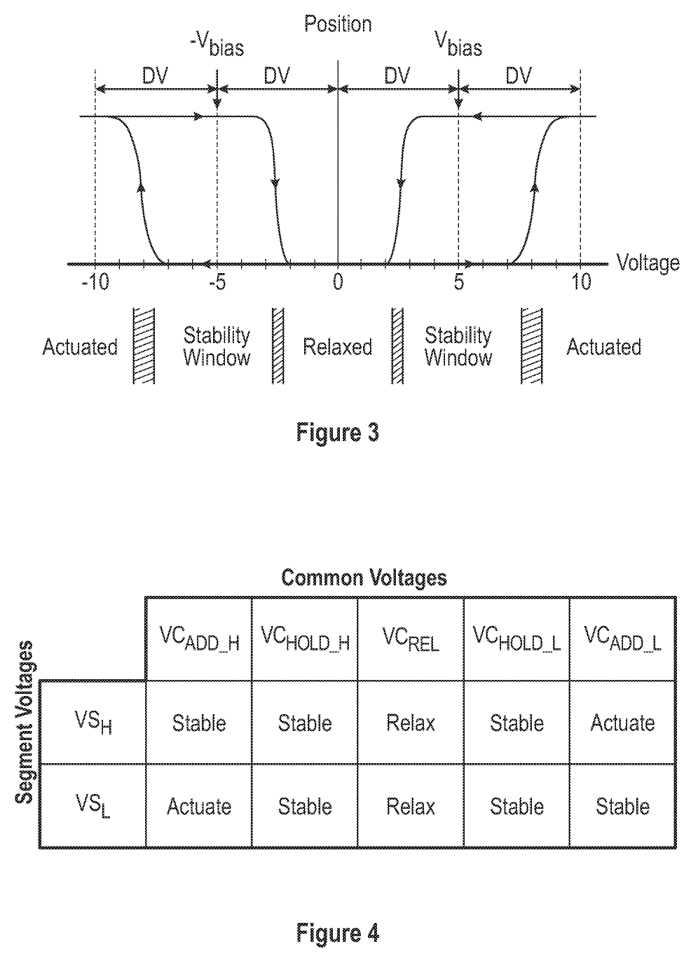

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

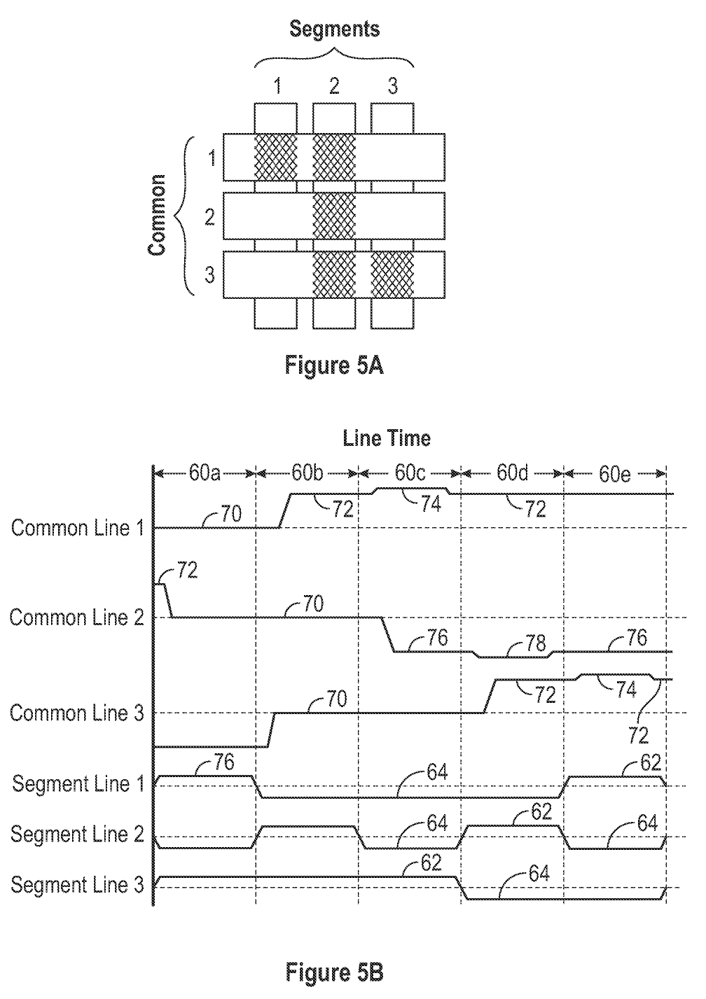

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

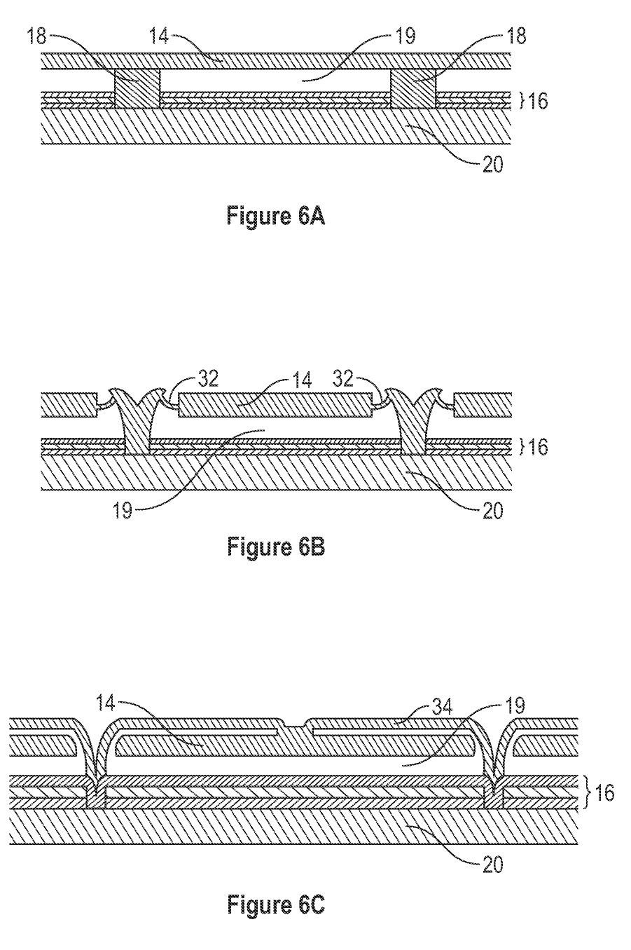

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

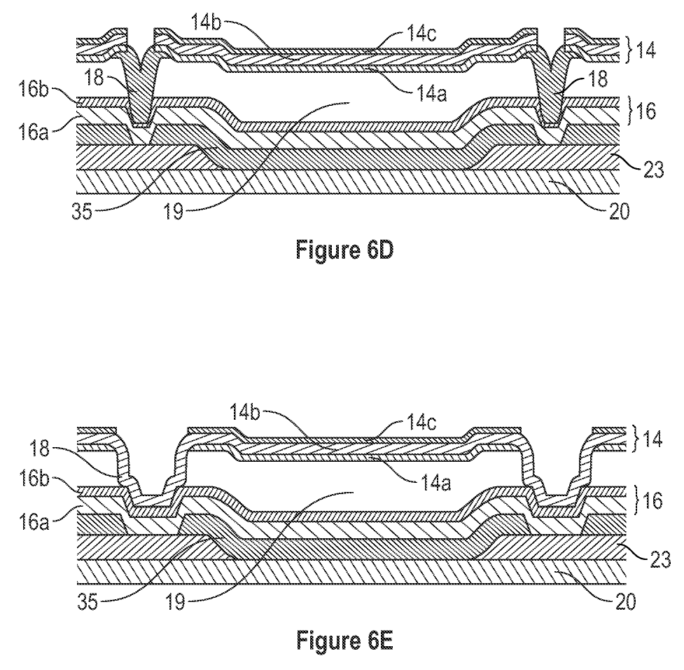

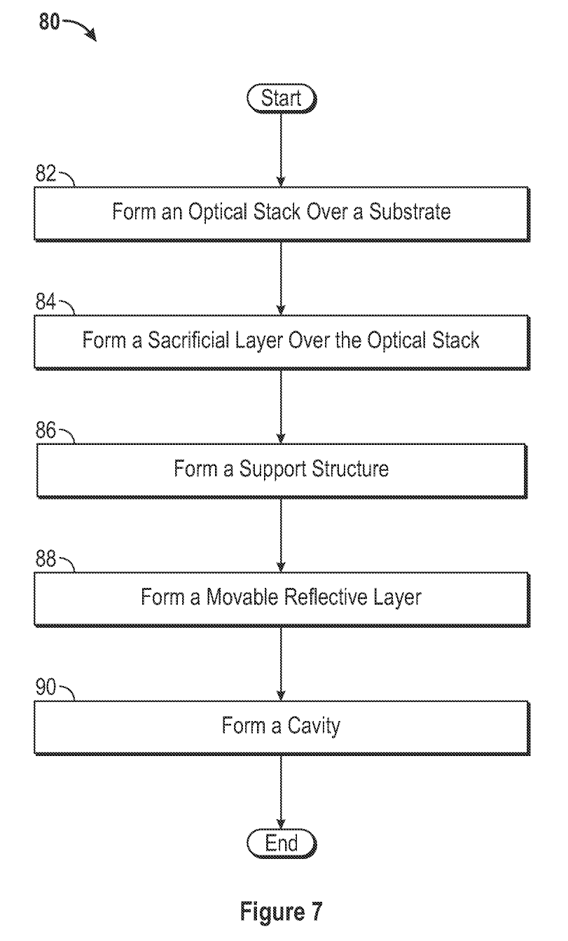

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

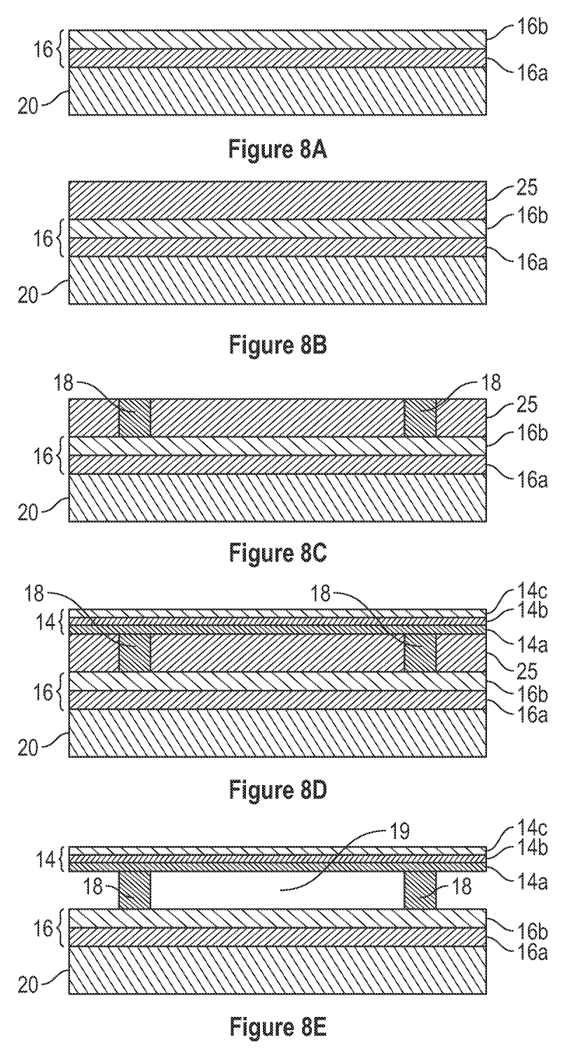

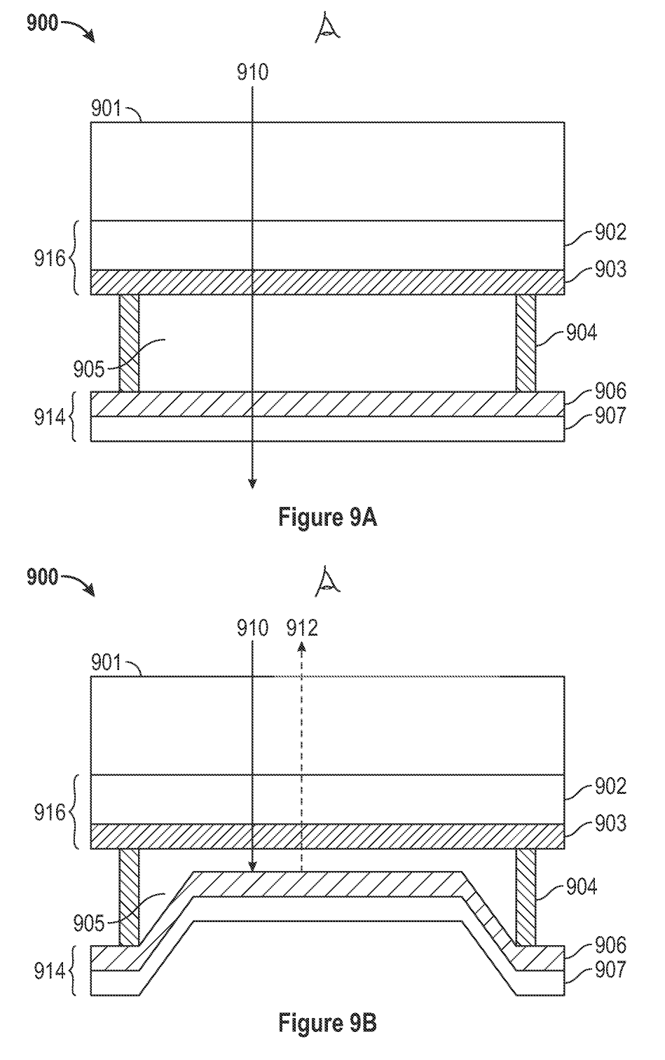

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

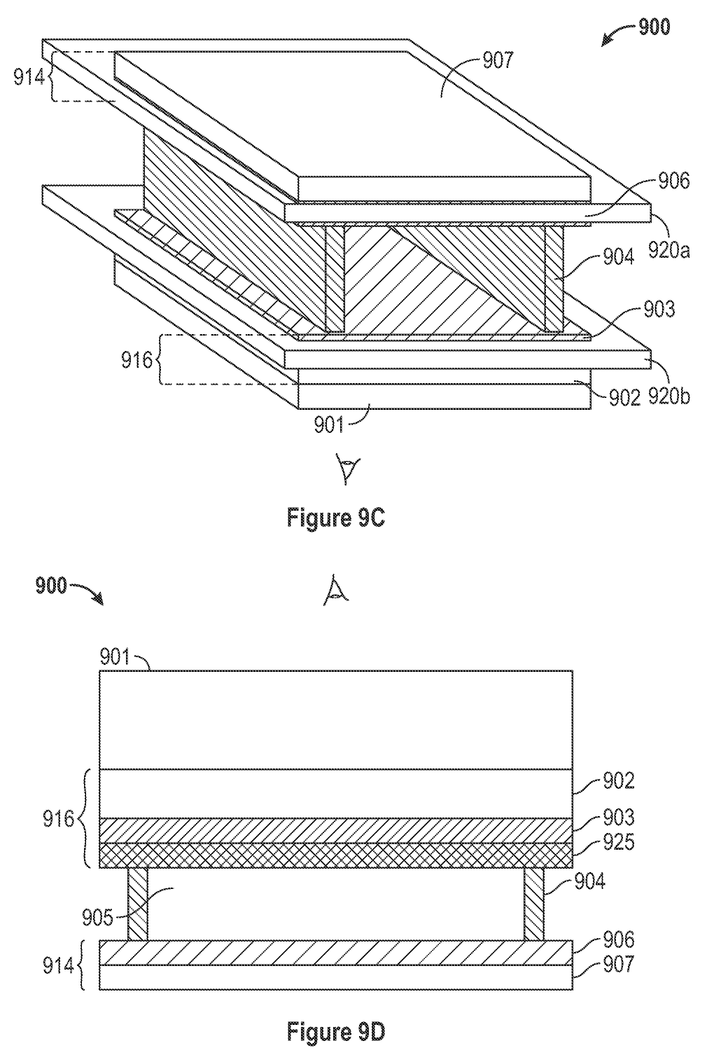

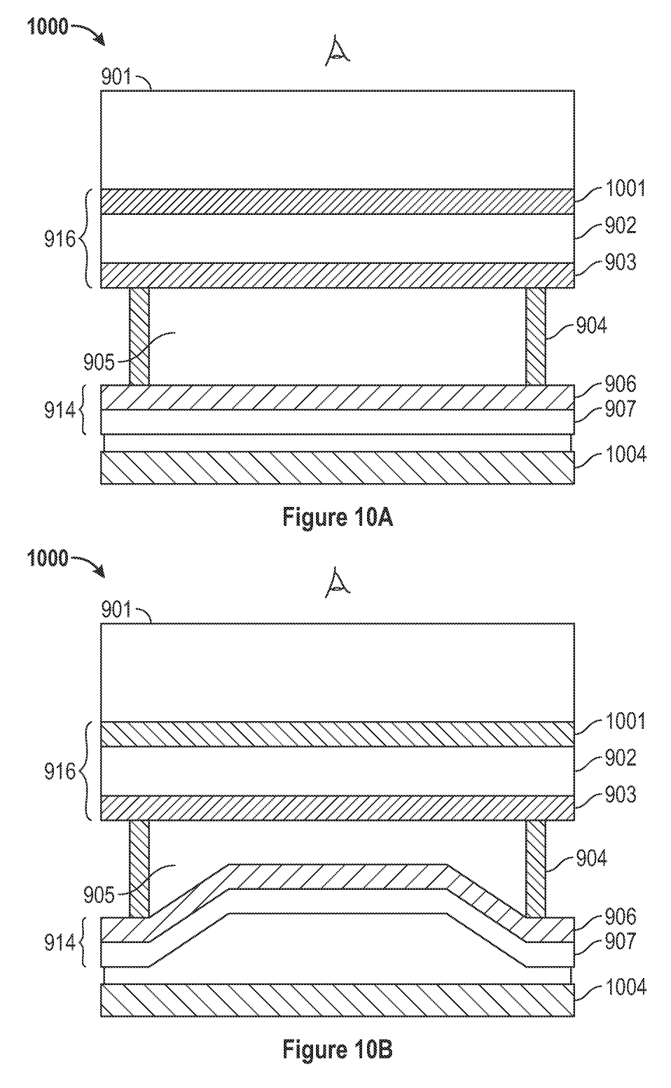

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

As discussed above, in various implementations, the interferometric modulator can be actuated between two positions, or at least two positions in some implementations, such that the interferometric modulator appears non-reflective (in the visible range, for example, dark, dark blue, dark purple or black) in one state and reflective to display a color (for example, red, blue, green) in another state. In some implementations, instead of displaying a color in the reflective state, the interferometric modulator can be configured to display white in the reflective state by reflecting almost uniformly all the wavelengths in the visible region. Such an interferometric modulator that can be switched from appearing dark or black in the non-reflective state to appearing white in the reflective state may be advantageous to provide grey scale control in display devices.

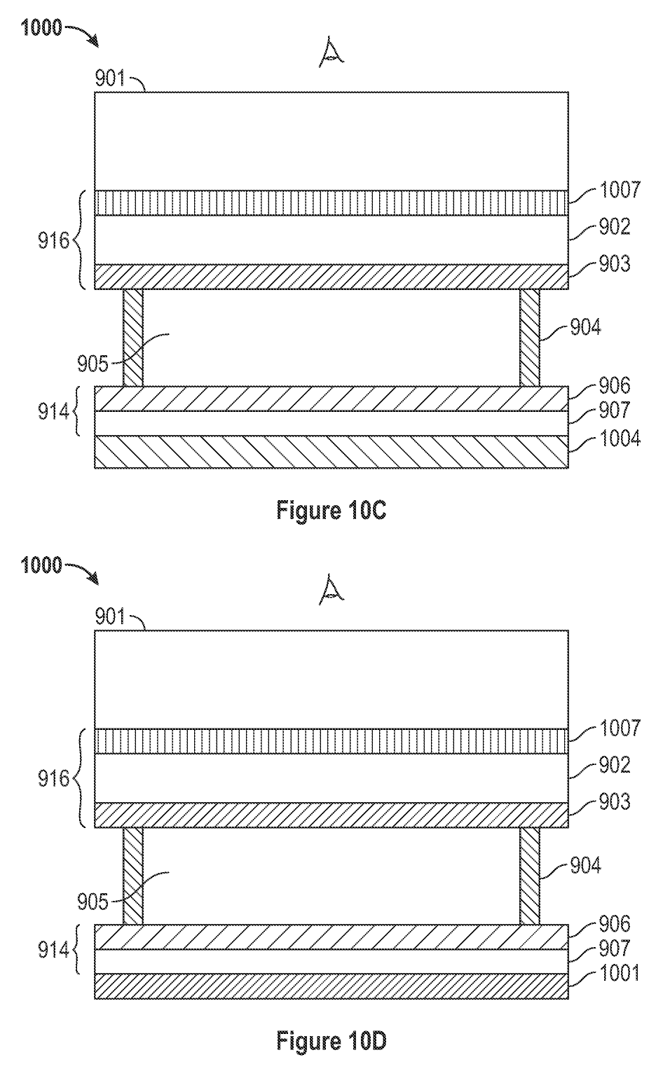

FIGS. 9A-9D illustrate implementations of an electromechanical systems device 900, which can include an interferometric modulator, that can be switched between a transmissive state and a reflective state. In various implementations, the electromechanical systems device 900 can include an interferometric modulator that operates in accordance with the principles set forth above. The electromechanical systems device 900 can include a substrate 901, an index matching layer 902, at least partially transmissive and partially reflective layers 903, 906 and a dielectric layer 907. The index matching layer 902 and the at least partially transmissive and partially reflective layer 903 together can form at least a portion of an optical stack 916 that is disposed over the substrate 901. In various implementations, the optical stack 916 can be similar to the optical stack 16 discussed above. The at least partially transmissive and partially reflective layer 906 is supported over the substrate 901 by posts 904 such that the layer 906 is separated from the layer 903 by a gap 905. Such posts 904 can include, but is not limited to, such structure as is illustrated in FIGS. 6a-6E.

The gap 905 can include a low refractive index substance having a refractive index lower than refractive index of the materials included in the substrate 901, the index matching layer 902, the at least partially transmissive and partially reflective layers 903, 906 and the dielectric layer 907. In some implementations, one or more gases (e.g., gases air, nitrogen, and argon) can be disposed in the gap 905. In some implementations, the gap 905 can be (at least partially) devoid of air or a gas, and be in a vacuum state. The at least partially transmissive and partially reflective layer 906 along with the dielectric layer 907 can together constitute a movable layer 914 that can be moved or actuated to switch the electromechanical systems device 900 from a transmissive state to a reflective. In various implementations, the movable layer 914 can be similar to the movable reflective layer 14 discussed above. The movement or actuation of the movable layer 914 can be accomplished by the application of a force, such as, for example, an electrostatic force or a mechanical force. In some implementations, the movement or actuation of the movable layer 914 can be accomplished using pressure differentials. For example, in some implementations a vacuum is used to move the movable layer 914.

In other implementations, the movable layer 914 and the optical stack can include electrodes or conductor layers for moving the movable layer 914 using electrostatic forces, as described herein. As illustrated in FIG. 9C, another implementation can have a frame 920a, that includes a conductive material, disposed surrounding part or all of the movable layer 914. The frame 920a can be configured as an electrode. In such implementations, another frame 920b that includes a conducting material can be disposed around the optical stack 916, forming another electrode. The movable layer 914 can be actuated using electrostatic force generated between the two frames 920a and 920b. The frames 920a and 920b can include a metal such as, for example, aluminum, copper, silver or gold. In various implementations, the frames 920a and 920b can include conducting materials other than metals.

The substrate 901 can be transparent and can include glass or a material that is transmissive to light (e.g., acrylic, plastic, etc.) so as to allow a viewer to see through the substrate 901. The index matching layer 902 can include aluminum oxide (Al₂O₃). The index matching layer 902 is used to match the refractive index of the at least partially transmissive and partially reflective layer 903 with the refractive index of the substrate 901. The index matching layer 902 can have a thickness between approximately 60 nm and approximately 90 nm. The at least partially transmissive and partially reflective layers 903 and/or 906 can include a material that has a real part (n) of the complex index of refraction (n+ik) greater than approximately 3.0 and a low (for example, approximately 0 or less than 0.1) imaginary part (or extinction coefficient characteristic, k) of the complex index of refraction (n+ik). Materials having a high refractive index (n) and a low extinction coefficient characteristic (k) can be desirable since these materials can provide an increased front surface reflection and absorb a very small percentage of light. For example, almost 30% of the light incident on a front surface of the partially transmissive and partially reflective layers 903 and/or 906 can be reflected if the partially transmissive and partially reflective layers 903 and/or 906 includes a material having a refractive index (n) of approximately 3.0. In various implementations, the extinction coefficient characteristic, k can have a low value, for example, between approximately 0 and approximately 0.2 such that the at least partially transmissive and partially reflective layers 903 and 906 absorb a very small percentage of the incident light. For example, in some implementations, the at least partially transmissive and partially reflective layers 903 and 906 absorb less than 1% of the incident light. In various implementations, the at least partially transmissive and at least partially reflective layers 903 and 906 can include Gallium Phosphide (GaP), having the real part of the complex index of refraction equal to approximately 3.5 and the imaginary part of the complex index of refraction less than approximately 0.1 (for example, equal to approximately zero (0)). The imaginary part of the complex index of refraction, also known as the extinction coefficient, provides a measure of the absorption of light. Since, the extinction coefficient for GaP is equal to approximately zero (0), very little incident light is absorbed by GaP thus providing increased reflectance in the mirror state and increased transmittance in the clear state. In various implementations, the conductance of the at least partially transmissive and at least partially reflective layers 903 and 906 including GaP can be increased by doping GaP with impurities. The thickness of the at least partially transmissive and partially reflective layers 903 and/or 906 can be between approximately 20 nm and approximately 40 nm. In various implementations, the dielectric layer 907 can include silica (SiO₂). The thickness of the dielectric layer 907 can be between approximately 60 nm and approximately 100 nm. The dielectric layer 907 can provide a spring restoring force. The dielectric layer 907 can advantageously serve to provide stiffness to the device structure. The dielectric layer 907 can be useful in providing mechanical stability to the device structure. In various implementations, the dielectric layer 907 can be eliminated. In such devices, the layers 903 and 906 are designed to have a desired stiffness to provide the required spring restoring force.

In various implementations, the partially transmissive and partially reflective layers 903 and 906 can be conductive. In some implementations, the conductive partially transmissive and partially reflective layers 903 and 906 can be configured, and used, as electrodes to receive drive currents and/or voltages from a driver circuit for electrostatically actuating the movable layer 914. In some implementations where the partially transmissive and partially reflective layers 903 and 906 are conductive, a layer of insulating material, 925, for example, an oxide (e.g., SiO₂), can be disposed between the partially transmissive and partially reflective layers 903 and 906 to prevent an electrical short, as illustrated in FIG. 9D. As illustrated in FIG. 9D, the layer of insulating material 925 can be included in the optical stack 916. Alternately, in some implementations, the layer of insulating material can be included in the movable layer 914. In some implementations, the partially transmissive and partially reflective layers 903 and 906 can have a resistivity of approximately 100 ohm-meter such that the partially transmissive and partially reflective layers 903 and 906 can be brought into contact when actuated electrostatically in the absence of an insulating layer without causing an electrical short.

When the electromechanical systems device 900 is in the un-actuated state such that movable layer 914 is farther apart from the optical stack 916, the electromechanical systems device 900 is in a transmissive state such that a ray of light 910 that is incident on the device 900 through the substrate 901 is transmitted through the optical stack 916 and movable layer 914 and out of the device 900. In the transmissive state the device 900 appears clear to a viewer viewing the device 900 through the substrate 901. In the actuated state as illustrated in FIG. 9B, the movable layer 914 is brought closer to or against the optical stack 916 such that a ray of light 910 that is incident on the device 900 through the substrate 901 is reflected by the movable layer 914 such that the device appears reflective or “mirror like” to a viewer viewing the device 900 through the substrate 901.

In various implementations, the materials for the various layers of the electromechanical systems device 900 and the thickness of the various layers of the electromechanical systems device 900 can be selected such that incident light over a wide wavelength range is reflected almost uniformly to provide a reflectance spectrum that is flat over a wide wavelength range. For example, the reflectance spectrum of the electromechanical systems device 900 can be flat over a bandwidth of approximately 100 nm. As another example, the reflectance spectrum of the electromechanical systems device 900 can be flat over a bandwidth of approximately 300 nm. In various implementations, the reflectance spectrum of the electromechanical systems device 900 can be flat over the entire visible region. In some implementations, the reflectance spectrum of the electromechanical systems device 900 can have a full width at half maximum (FWHM) of approximately 100 nm, approximately 200 nm or approximately 300 nm. In various implementations, a reflectance spectrum that is flat over the entire visible range can be obtained by bringing the partially transmissive and partially reflective layers 903 and/or 906 of the electromechanical systems device 900 into contact with each other. In various implementations, where the electromechanical systems device 900 is activated electrostatically, the width of the reflectance spectrum or the FWHM of the reflectance spectrum can be increased by reducing the thickness of the insulating layer (for example, the oxide layer) that is between the partially transmissive and partially reflective layers 903 and/or 906. For example, an insulating layer having a thickness between approximately 20 nm and approximately 40 nm can be used to achieve a reflectance spectrum with a FWHM of at least 50 nm. As another example, in some implementations, the partially transmissive and partially reflective layers 903 and 906 can have a certain impedance characteristic, in addition to being conductive, such that they can be brought into contact without causing an electrical short. Accordingly, in some implementations the insulating layer between the partially transmissive and partially reflective layers 903 and 906 can be omitted to achieve a reflectance spectrum with a FWHM of at least 100 nm.

The electromechanical systems device 900 can be manufactured using a manufacturing process similar to process 80 illustrated in FIGS. 8A-8E. For example, the partially transmissive and partially reflective layer 903 can be deposited on the index matching layer 902 using deposition techniques such as physical vapor deposition (PVD) (e.g., sputtering), plasma-enhanced chemical vapor deposition (PECVD), thermal chemical vapor deposition (thermal CVD), or spin-coating. As another example, the partially transmissive and partially reflective layer 906 can be deposited on a sacrificial layer 25 formed during manufacturing using deposition techniques such as PVD (e.g., sputtering), PECVD, thermal CVD, or spin-coating.

Such electromechanical systems devices can be used as a smart window that can be actuated electrically or mechanically to control the amount of light entering a window. Various implementations of the electromechanical systems devices operating in accordance with the principles set forth above can be used as privacy screens, camera shutter or any other application where it is desirable to control the amount of light transmitted. Various implementations of the electromechanical systems devices described herein can also be used in display devices as discussed below.

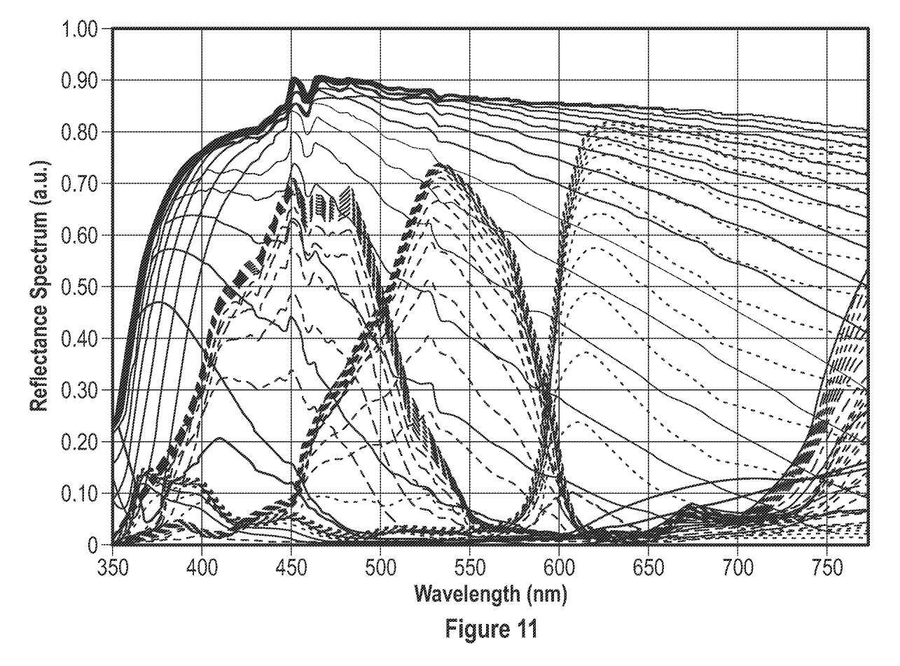

FIGS. 10A-10D illustrate implementations of a display element that include an electromechanical systems device that operates in accordance with the principles set forth above. The electromechanical systems device 900 is modified by providing a black backing 1004 disposed rearward of the movable layer 914 and including an optical filter 1001 in the optical stack 916. The electromechanical systems device 1000 illustrated in FIGS. 10A and 10B can switch between a dark state and a color state. Such a device 1000 can be used in various display applications.

For example, when the electromechanical systems device 1000 is in the un-actuated state, as illustrated in FIG. 10A, such that the movable layer 914 is farther apart from the optical stack 916, the electromechanical systems device 1000 is in a transmissive state. In the transmissive state, a viewer viewing the device 1000 through the substrate 901 can perceive the black backing 1004 such that the device 1000 appears black or dark to the viewer. In the actuated state, as illustrated in FIG. 10B, the movable layer 914 is brought closer to/against the optical stack 916 such that light incident through the substrate 901 is filtered by the color filter 1001 and reflected by the movable layer 914. Thus, the device 1000 appears colored to a viewer viewing the device 1000 through the substrate 901. The color perceived by the viewer in the actuated state is the color transmitted by the color filter 1001. For example, if the color filter 1001 is configured to transmit wavelengths in the red portion of the visible range, then the device 1000 will appear red to a viewer. As another example, if the color filter 1001 is configured to transmit wavelengths in the blue portion of the visible range, then the device 1000 will appear blue to a viewer. Accordingly, the device 1000 can be used as a display pixel, or part of a display pixel, in a display device.

As discussed above, the implementations shown in FIGS. 10A-10D function as direct-view devices, in which images are viewed from the front side of the substrate 901, i.e., the side opposite to that upon which the movable layer 914 is arranged. In these implementations, the black backing 1004 which is behind or rearward of the movable layer 914 will not be visible in the actuated state and thus will not impact or negatively affect the image quality of the display device, because the movable layer 914 optically shields the black backing 1004 in the actuated state.

FIG. 10C illustrates an implementation of an electromechanical systems device 1000 that is capable of switching between a dark state and a white state for use in display applications. In the implementation illustrated in FIG. 10C, a diffuser 1007 is included in the optical stack 916 such that the device 1000 appears white to the viewer in the actuated state and black in the un-actuated state. Such a device 1000 can be useful in providing better grey scale control. Additionally, since the device 1000 can be designed to have a flat reflectance spectrum over the entire visible range and absorb a small percentage (for example, less than 1%) of the incident light, the device 1000 can appear very bright in the white state. In some implementations, the device 1000 can display a white state that is approximately 30% to approximately 60% brighter than the white state displayed by other available display devices.

FIG. 10D illustrates an implementation of an electromechanical systems device 1000 that is capable of switching between a color state and a white state for use in display applications. In the implementation illustrated in FIG. 10D, a diffuser 1007 is included in the optical stack 916 such that the device 1000 appears white to the viewer in the actuated state. A color filter 1001 (for example, a red, green or blue color filter) is provided rearward of the movable layer 914 such that the device 1000 appears colored in the un-actuated state.

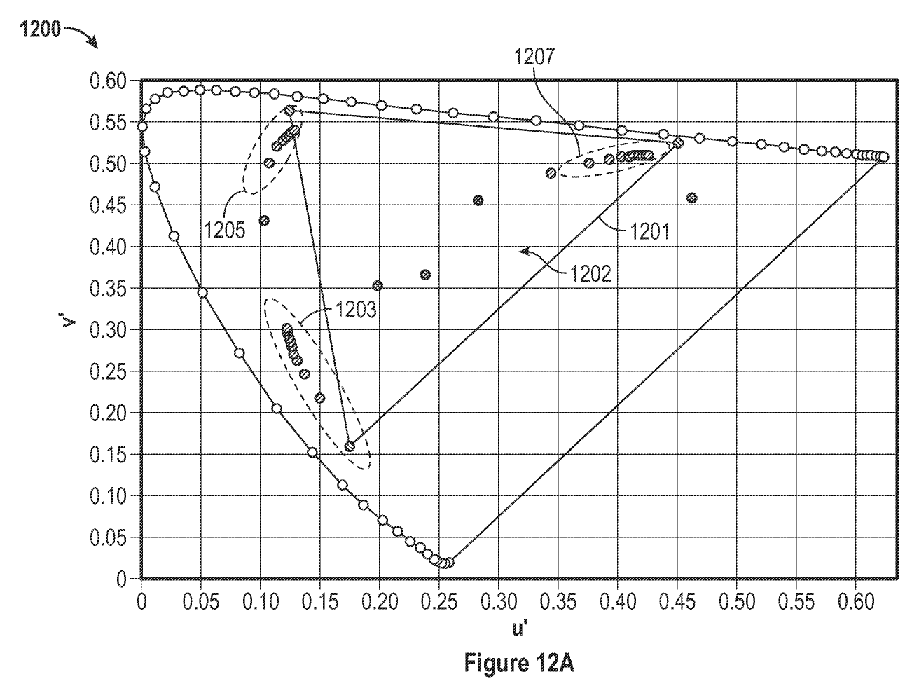

FIG. 11 illustrates a simulated reflectance spectrum 1100 of an implementation of a display element similar to the display element illustrated in FIGS. 10A-10D. The group of traces 1101 corresponds to the simulated reflectance of the display element in the blue region of the visible spectrum for different positions of the movable layer 914. The group of traces 1102 corresponds to the simulated reflectance of the display element in the green region of the visible spectrum for different positions of the movable layer 914. The group of traces 1103 corresponds to the simulated reflectance of the display element in the red region of the visible spectrum for different positions of the movable layer 914. As observed from FIG. 11, almost 60% or higher of the light incident on the device in the blue, green and red regions of the visible spectrum is reflected by the display element in the reflective or actuated state. Accordingly, the color displayed by the display element can be brighter than the color displayed by other available display devices. It is also observed from FIG. 11 that the reflectance is almost uniform in the blue, green and red regions of the visible spectrum illustrating that the display element has a flat reflectance spectrum over the entire visible range.

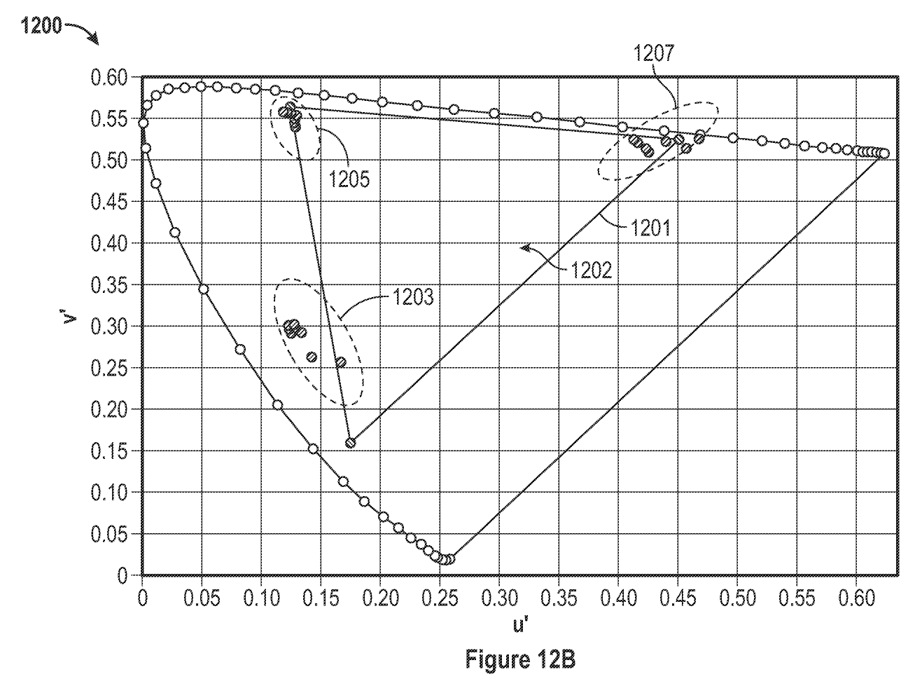

FIGS. 12A and 12B illustrate simulated chromaticity diagram 1200 of an implementation of a display device including a plurality of display elements similar to the display element illustrated in FIGS. 10A-10D. The chromaticity diagram 1200 illustrates the different colors that can be produced by the display device. A wide range of colors are produced in such a display device by varying the relative intensity of light produced by the plurality of display elements. A chromaticity diagram illustrates how a display may be controlled to generate the mixtures of colors such as red, green, and blue that is perceived by the human eye as other colors. The horizontal and vertical axes of FIGS. 12A and 12B define a chromaticity coordinate system (for example, a coordinate system corresponding to the CIE 1976 (L*, u*, v*) color space) on which color values may be depicted. For example, region 1203 corresponds to the various shades, tints, chroma and/or hues produced by the display element in the blue region of the visible spectrum. As another example, region 1205 corresponds to the various shades, tints, chroma and/or hues produced by the display element in the green region of the visible spectrum light. As yet another example, region 1207 corresponds to the various shades, tints, chroma and/or hues produced by the display element in the red region of the visible spectrum. The triangular trace 1201 encloses a region 1202 that corresponds to the range of colors that can be produced by mixing the light produced in regions 1203, 1205 and 1207. This range of colors may be referred to as the color gamut of the display device. As observed from the color gamut 1202, the display element can be configured to produce a white point corresponding to CIE Standard Illuminant D65 having a correlated color temperature of approximately 6500 K.

FIG. 12B illustrate a simulated color gamut produced by the display when angle of incidence of the light incident on the display element varies from approximately 0 degrees with respect to a surface normal of the display element to approximately 60 degrees with respect to the surface normal. As can be observed in FIG. 12B, the display element does not exhibit large deviations in the color produced as the angle of incidence varies. Accordingly, the color produced by the display element substantially remains the same as the angle of incidence varies. Conversely, a viewer viewing the display element perceives little shift in color as the view angle varies from close to the surface normal to approximately 60 degrees from the surface normal. This feature may be advantageous in display devices configured to be viewable over a wide angular width or range.

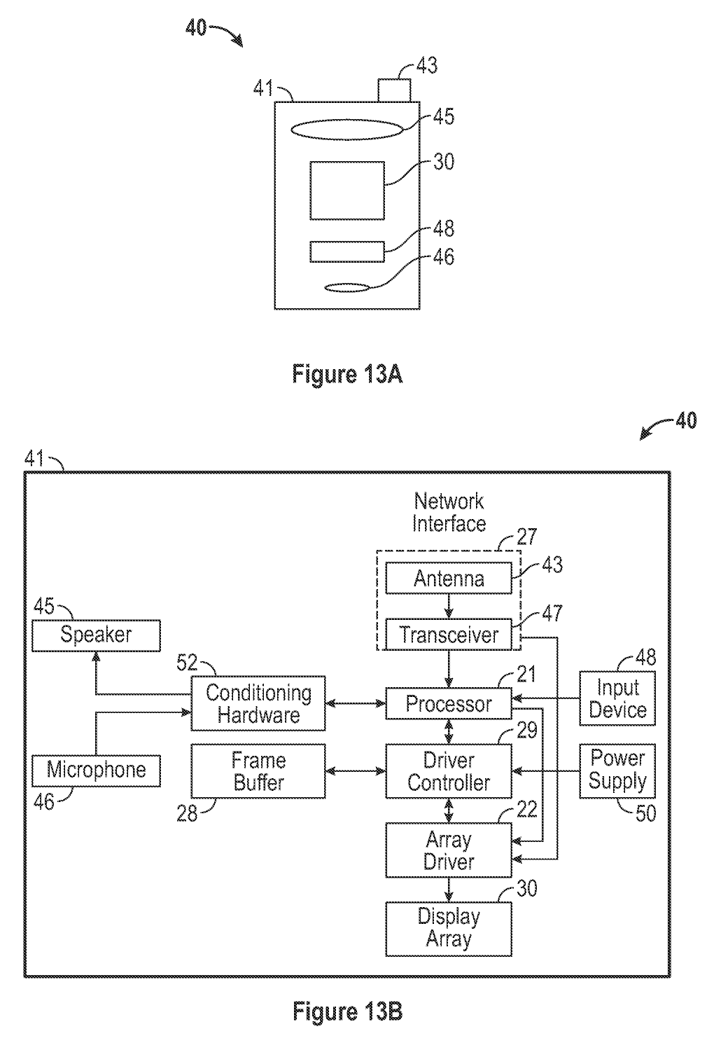

FIGS. 13A and 13B show examples of system block diagrams illustrating a display device 40 that includes a plurality of interferometric modulators. In various implementations, the display device 40 can include a plurality of electromechanical systems device 900, 1000. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 13B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An electromechanical device comprising:
a substrate;
an optical stack disposed over the substrate, the optical stack including an index matching layer and a first at least partially transmissive and at least partially reflective layer, the index matching layer disposed between the substrate and the first layer; and
a movable layer disposed over the optical stack, the movable layer and the optical stack defining a cavity therebetween, the movable layer configured to move through the cavity, the movable layer including
a second at least partially transmissive and at least partially reflective layer, and
a dielectric layer disposed on the second layer such that the second layer is between the cavity and the dielectric layer;
wherein the index of refraction of the first and the second layer is greater than approximately 3.0.

2. The electromechanical device of claim 1, wherein the first and the second layer have an extinction coefficient characteristic less than approximately 0.1.

3. The electromechanical device of claim 1, wherein the index matching layer includes aluminum oxide (Al₂O₃).

4. The electromechanical device of claim 1, wherein the first layer includes gallium phosphide (GaP).

5. The electromechanical device of claim 1, wherein the second layer includes gallium phosphide (GaP).

6. The electromechanical device of claim 1, wherein the index matching layer is configured to match the refractive index of the first layer with the refractive index of the substrate.

7. The electromechanical device of claim 1, wherein the movable layer is movable between a first position when the cavity is collapsed to a second position when the cavity is not collapsed, the first position being closer to the optical stack than the second position.

8. The electromechanical device of claim 7, wherein the device is configured to reflect light incident on the substrate when the movable layer is in the first position.

9. The electromechanical device of claim 7, wherein the device is transmissive of light incident on the substrate when the movable layer is in the second position.

10. The electromechanical device of claim 7, wherein the device is configured to move the movable layer to the first and the second position by the application of electrostatic forces.

11. The electromechanical device of claim 7, device is configured to move the movable layer to the first and the second position by the application of mechanical forces.

12. The electromechanical device of claim 7, device is configured to move the movable layer to the first and the second position using vacuum.

13. The electromechanical device of claim 1, wherein the cavity is an interferometric cavity.

14. The electromechanical device of claim 1, wherein the first layer has a thickness between approximately 20 nanometers and approximately 40 nanometers.

15. The electromechanical device of claim 1, wherein the second layer has a thickness between approximately 20 nanometers and approximately 40 nanometers.

16. The electromechanical device of claim 1, wherein the index matching layer has a thickness between approximately 60 nanometers and approximately 90 nanometers.

17. The electromechanical device of claim 1, wherein the dielectric layer has a thickness between approximately 60 nanometers and approximately 100 nanometers.

18. The electromechanical device of claim 1, wherein the cavity includes an insulating layer between the movable layer and the fixed optical stack.

19. The electromechanical device of claim 1, wherein the first layer has a resistivity of approximately 100 ohm-meter.

20. The electromechanical device of claim 1, wherein the second layer has a resistivity of approximately 100 ohm-meter.

21. The electromechanical device of claim 1, further comprising:
a display;
a processor that is configured to communicate with the display, the processor being configured to process image data; and
a memory device that is configured to communicate with the processor.

22. The electromechanical device of claim 21, further comprising a driver circuit configured to send at least one signal to the display.

23. The electromechanical device of claim 22, further comprising a controller configured to send at least a portion of the image data to the driver circuit.

24. The electromechanical device of claim 21, further comprising an image source module configured to send the image data to the processor.

25. The electromechanical device of claim 24, wherein the image source module includes at least one of a receiver, transceiver, and transmitter.

26. The electromechanical device of claim 21, further comprising an input device configured to receive input data and to communicate the input data to the processor.

27. An electromechanical device comprising:
a substrate;
a optical stack disposed over the substrate, the optical stack including a means for refractive index matching and a first means for partially transmitting and partially reflecting light, the refractive index matching means disposed between the substrate and the first partially transmitting and partially reflecting means; and
a movable layer disposed over the optical stack, the movable layer and the optical stack including a means for producing optical resonance therebetween, the movable layer configured to move through the optical resonance producing means using a means for actuating the movable layer, the movable layer including
a second means for partially transmitting and partially reflecting light, and
a dielectric layer disposed on the second partially transmitting and partially reflecting means such that the second partially transmitting and partially reflecting means is between the optical resonance producing means and the dielectric layer;
wherein the index of refraction of the first and second partially transmitting and partially reflecting means is greater than approximately 3.0.

28. The electromechanical device of claim 27, wherein the refractive index matching means includes a refractive index matching layer, or the first means for partially transmitting and partially reflecting light includes a partially transmissive and a partially reflective layer, or the second means for partially transmitting and partially reflecting light includes a partially transmissive and a partially reflective layer, or the optical resonance producing means includes an optical resonant cavity.

29. The electromechanical device of claim 27, wherein the actuating means includes a device configured to provide an electrostatic force.

30. The electromechanical device of claim 27, wherein the actuating means includes a device configured to provide a mechanical force.

31. The electromechanical device of claim 27, wherein first and second partially transmitting and partially reflecting means have an absorption coefficient characteristic less than approximately 0.1.

32. A method of manufacturing an electromechanical device, the method comprising:
providing a substrate;
providing an optical stack, the optical stack disposed over the substrate, the optical stack including a refractive index matching layer and a first at least partially transmissive and partially reflective, the refractive index matching layer disposed between the substrate and the first partially transmissive and partially reflective layer; and
providing a movable layer disposed over the optical stack, the movable layer and the optical stack including a cavity therebetween, the movable layer configured to move through the cavity, the movable layer including:
a second at least partially transmissive and a partially reflective layer having a refractive index greater than approximately 3.0 and an absorption coefficient characteristic less than approximately 0.1, and
a dielectric layer disposed on the conducting layer such that the second partially transmissive and partially reflective layer is between the cavity and the dielectric layer.

33. The method of claim 32, wherein the first partially transmissive and partially reflective layer is formed by a process including at least one of: physical vapor deposition, chemical vapor deposition, plasma-enhanced chemical vapor deposition, thermal chemical vapor deposition and spin-coating.

34. The method of claim 32, wherein the second partially transmissive and partially reflective layer is formed by a process including at least one of: physical vapor deposition, chemical vapor deposition, plasma-enhanced chemical vapor deposition, thermal chemical vapor deposition and spin-coating.

35. The method of claim 32, further comprising providing a conductive frame around the movable layer, the conductive frame configured for use in actuating the movable layer.
